(19) United States
(12) Patent Application Publication
(10) Pub. No.: US 2024/0284685 A1
(43) Pub. Date: Aug. 22, 2024

(54) SEMICONDUCTOR DEVICE AND MANUFACTURING METHOD THEREOF

(71) Applicant: Kioxia Corporation, Tokyo (JP)

(72) Inventors: Ryoya HASEBE, Yokkaichi (JP); Tomoki AKIMOTO, Yokkaichi (JP)

(73) Assignee: Kioxia Corporation, Tokyo (JP)

(21) Appl. No.: 18/443,882

(22) Filed: Feb. 16, 2024

(30) Foreign Application Priority Data
Feb. 21, 2023 (JP) 2023-025399

(51) Int. Cl. H10B 80/00; H01L 23/00; H01L 25/00; H01L 25/065; H01L 25/18

(52) U.S. Cl. CPC H10B 80/00; H01L 24/08; H01L 25/0657; H01L 25/18; H01L 25/50; H01L 2224/08145; H01L 2225/06506; H01L 2225/06562; H01L 2225/06586; H01L 2924/1431; H01L 2924/14511

(57) ABSTRACT

A semiconductor device according to the present embodiment includes a semiconductor chip including a first chip and a second chip. The second chip is joined to the first chip on the first chip such that the second chip is electrically connected to the first chip. The area of the second chip is smaller than the area of the first chip. The second chip is provided in a first region on an upper surface of the first chip and the first chip includes a first pad exposed from the first chip in a second region different from the first region.

### CROSS REFERENCE TO RELATED APPLICATIONS

This application is based upon and claims the benefit of priority from the prior Japanese Patent Application No. 2023-025399, filed on Feb. 21, 2023, the entire contents of which are incorporated herein by reference.

### FIELD

The embodiments of the present invention relate to a semiconductor device and a manufacturing method thereof.

### BACKGROUND

In a semiconductor in which two wafers are bonded, an unnecessary region increases when there is a mismatch between the sizes (areas) of semiconductor elements of the respective wafers.

### BRIEF DESCRIPTION OF THE DRAWINGS

FIG. 1 is a cross sectional view illustrating an example of the configuration of a semiconductor device according to a first embodiment;

FIG. 2 is a cross sectional view illustrating the example of the configuration of the semiconductor device according to the first embodiment;

FIG. 3 is a cross sectional view illustrating the example of the configuration of the semiconductor device according to the first embodiment;

FIG. 4 is a cross sectional view illustrating the example of the configuration of the semiconductor device according to the first embodiment;

FIG. 5 is a cross sectional view illustrating an example of the configuration of a memory cell array and a transistor according to the first embodiment;

FIG. 6 is a cross sectional view illustrating an example of the configuration of a column-shaped part according to the first embodiment;

FIG. 7A is a cross sectional view illustrating an example of a method of manufacturing the semiconductor device according to the first embodiment;

FIG. 7B is a perspective view illustrating the example of the semiconductor device manufacturing method, following FIG. 7A;

FIG. 7C is a perspective view illustrating the example of the semiconductor device manufacturing method, following FIG. 7B;

FIG. 7D is a perspective view illustrating the example of the semiconductor device manufacturing method, following FIG. 7C;

FIG. 7E is a perspective view illustrating the example of the semiconductor device manufacturing method, following FIG. 7D;

FIG. 7F is a perspective view illustrating the example of the semiconductor device manufacturing method, following FIG. 7E;

FIG. 7G is a perspective view illustrating the example of the semiconductor device manufacturing method, following FIG. 7F;

FIG. 7H is a perspective view illustrating the example of the semiconductor device manufacturing method, following FIG. 7G;

FIG. 8 is a diagram illustrating an example of the sizes of a circuit chip and an array chip according to the first embodiment;

FIG. 9 is a cross sectional view illustrating an example of the configuration of a semiconductor device according to a comparative example;

FIG. 10 is a diagram illustrating an example of the sizes of a circuit chip and an array chip according to the comparative example;

FIG. 11 is a cross sectional view illustrating an example of the configuration of a semiconductor device according to a second embodiment;

FIG. 12 is a cross sectional view illustrating an example of the configuration of a semiconductor device according to a third embodiment;

FIG. 13 is a cross sectional view illustrating an example of the configuration of a semiconductor device according to a fourth embodiment;

FIG. 14 is a cross sectional view illustrating an example of the configuration of a semiconductor device according to a fifth embodiment;

FIG. 15A is a cross sectional view illustrating an example of a method of manufacturing the semiconductor device according to the fifth embodiment;

FIG. 15B is a perspective view illustrating the example of the semiconductor device manufacturing method, following FIG. 15A;

FIG. 16 is a cross sectional view illustrating an example of the configuration of a semiconductor device according to a sixth embodiment;

FIG. 17 is a cross sectional view illustrating an example of the configuration of a semiconductor device according to a seventh embodiment;

FIG. 18 is a cross sectional view illustrating an example of the configuration of a semiconductor device according to an eighth embodiment;

FIG. 19 is a cross sectional view illustrating an example of the configuration of a semiconductor device according to a ninth embodiment;

FIG. 20A is a cross sectional view illustrating an example of a method of manufacturing the semiconductor device according to the ninth embodiment;

FIG. 20B is a perspective view illustrating the example of the semiconductor device manufacturing method, following FIG. 20A;

FIG. 20C is a perspective view illustrating the example of the semiconductor device manufacturing method, following FIG. 20B;

FIG. 21 is a cross sectional view illustrating an example of the configuration of a semiconductor device according to a tenth embodiment; and

FIG. 22 is a cross sectional view illustrating an example of the configuration of a semiconductor device according to an eleventh embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a semiconductor chip including a first chip and a second chip. The second chip is joined to the first chip on the first chip such that the second chip is electrically connected to the first chip. The area of the second chip is smaller than the area of the first chip. The first chip further includes a first pad exposed from the first chip in a second region, which is different from a first region in which the second chip is provided on an upper surface of the first chip.

### First Embodiment

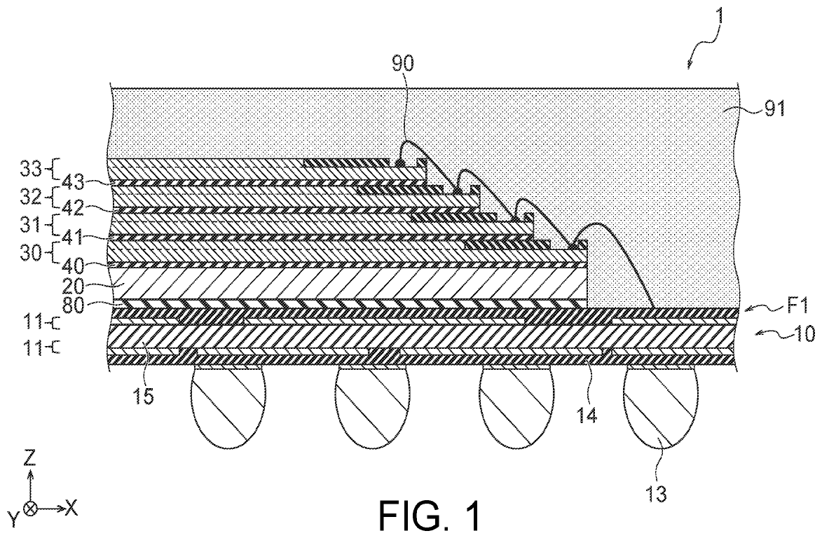

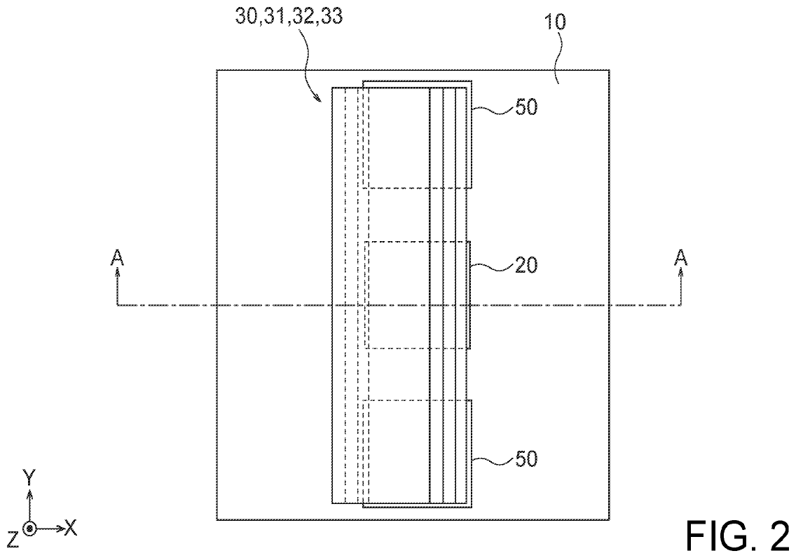

FIG. 1 is a cross sectional view illustrating an example of the configuration of a semiconductor device 1 according to a first embodiment. FIG. 2 is a plan view illustrating the example of the configuration of the semiconductor device 1 according to the first embodiment. Line A-A in FIG. 2 indicates a section corresponding to the cross sectional view of FIG. 1.

FIGS. 1 and 2 illustrate an X direction and a Y direction parallel to a front surface of a wiring substrate 10 and orthogonal to each other, and a Z direction orthogonal to the front surface of the wiring substrate 10. In the present specification, the positive Z direction is an upward direction, and the negative Z direction is a downward direction. The negative Z direction may or may not be aligned with the direction of gravity.

The semiconductor device 1 includes the wiring substrate 10, semiconductor chips 20 and 30 to 33, bonding layers 40 to 43, a spacer 50, a resin layer 80, a bonding wire 90, and a sealing resin 91. The semiconductor device 1 is, for example, a packaged NAND type flash memory.

The wiring substrate 10 may be a printed circuit board or interposer including wiring layers 11 and an insulating layer 15. A low resistance metal such as copper (Cu), nickel (Ni), or alloy thereof is used as the wiring layers 11. An insulating material such as glass epoxy resin is used as the insulating layer 15. In the diagrams, the wiring layers 11 are provided only on front and back surfaces of the insulating layer 15. However, the wiring substrate 10 may include a multi-layer wiring structure formed by stacking a plurality of wiring layers 11 and a plurality of insulating layers 15. The wiring substrate 10 may include a penetration electrode (column-shaped electrode) penetrating through front and back surfaces thereof like an interposer.

A solder resist layer 14 provided on a wiring layer 11 is provided on the front surface (surface F1) of the wiring substrate 10. The solder resist layer 14 is an insulating layer for protecting the wiring layer 11 from a metallic material (not illustrated) connecting the semiconductor chip 20 and the wiring layers 11 and for preventing short-circuit defect.

Another solder resist layer 14 provided on a wiring layer 11 is provided on a back surface of the wiring substrate 10. Metal bumps 13 are provided on the wiring layer 11 exposed through the solder resist layer 14. The metal bumps 13 are provided to electrically connect a non-illustrated other component to the wiring substrate 10.

The semiconductor chip 20 is, for example, a controller chip configured to control a memory chip. A non-illustrated semiconductor element is provided on a surface of the semiconductor chip 20 facing the wiring substrate 10. The semiconductor element may be, for example, a complementary metal oxide semiconductor (CMOS) circuit constituting a controller. An electrode pillar (not illustrated) electrically connected to the semiconductor element is provided on a back surface (lower surface) of the semiconductor chip 20. A low resistance metallic material such as copper, nickel, or alloy thereof is used as the electrode pillar.

A metallic material is provided around the electrode pillar as a connection bump. The electrode pillar is electrically connected through the metallic material to the wiring layer 11 exposed at an opening part of the solder resist layer 14. A low resistance metallic material such as solder, silver, or copper is used as the metallic material. Accordingly, the metallic material electrically connects the electrode pillar of the semiconductor chip 20 and the wiring layer 11 of the wiring substrate 10.

The resin layer 80 is provided in a region around the metallic material and a region between the semiconductor chip 20 and the wiring substrate 10. The resin layer 80 is, for example, cured underfill resin and covers and protects the circumference of the semiconductor chip 20.

The semiconductor chip 30 is, for example, a memory chip including an NAND type flash memory. The semiconductor chip 30 is provided with a semiconductor element (not illustrated) on its front surface (upper surface). The semiconductor element may be, for example, a memory cell array and its peripheral circuit (CMOS circuit). The memory cell array may be a stereoscopic memory cell array in which a plurality of memory cells are three-dimensionally disposed. The semiconductor chip 31 is bonded on the semiconductor chip 30 with the bonding layer 41 interposed therebetween. The semiconductor chip 32 is bonded on the semiconductor chip 31 with the bonding layer 42 interposed therebetween. The semiconductor chip 33 is bonded on the semiconductor chip 32 with the bonding layer 43 interposed therebetween. Similarly to the semiconductor chip 30, the semiconductor chips 31 to 33 are, for example, memory chips including an NAND type flash memory. The semiconductor chips 30 to 33 may be the same memory chip. In the diagrams, the semiconductor chip 20 as a controller chip as well as the semiconductor chips 30 to 33 as four memory chips are stacked. However, the number of stacked semiconductor chips may be three or less or may be five or more.

As illustrated in FIG. 2, the spacer 50 is provided, for example, on a side of the semiconductor chip 20. The spacer 50 is bonded to the front surface (upper surface) of the wiring substrate 10 with a bonding layer interposed therebetween. The semiconductor chips 30 to 33 are provided above the spacer 50 and the semiconductor chip 20. The material of the spacer 50 is, for example, silicon (Si) or polyimide.

The bonding wire 90 is connected to the wiring substrate 10 and optional pads of the semiconductor chips 30 to 33. For the connection through the bonding wire 90, the semiconductor chips 30 to 33 are stacked while being displaced as corresponding to the pads. The semiconductor chip 20 is flip-chip connected through the electrode pillar and thus not wire-bonded. However, the semiconductor chip 20 may be wire-bonded in addition to the connection through the electrode pillar.

The sealing resin 91 seals the semiconductor chips 20 and 30 to 33, the bonding layers 40 to 43, the spacer 50, the bonding wire 90, and the like. Accordingly, in the semiconductor device 1, the plurality of semiconductor chips 20 and 30 to 33 are constituted as one semiconductor package on the wiring substrate 10.

Details of the semiconductor chips 30 to 33 will be described below.

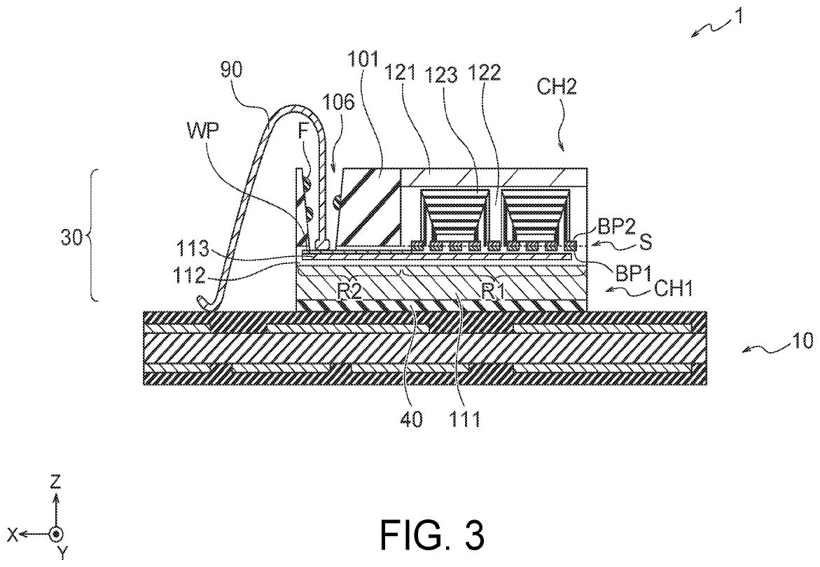

FIG. 3 is a cross sectional view illustrating the example of the configuration of the semiconductor device 1 according to the first embodiment. FIG. 3 illustrates the semiconductor chip 30. Although the semiconductor chip 30 will be described below, the semiconductor chips 31 to 33 have the same configuration as the semiconductor chip 30. Since the semiconductor chip 30 will be described in detail in the example illustrated in FIG. 3, illustration of the semiconductor chip 20 in FIG. 1 is omitted.

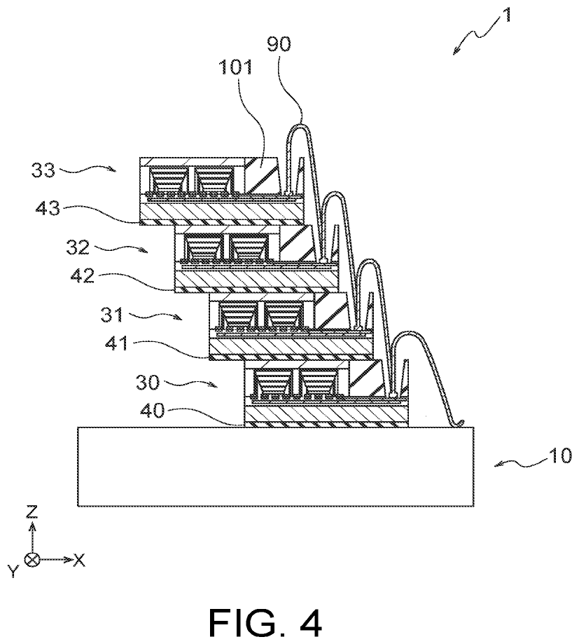

FIG. 4 is a cross sectional view illustrating an example of the configuration of the semiconductor device 1 according to the first embodiment. FIG. 4 illustrates a diagram in which the four semiconductor chips 30 to 33 are stacked. The right and left directions are inverted between FIGS. 3 and 4.

The semiconductor chip 30 includes a circuit chip CH1, an array chip CH2, and a spacer 101. The circuit chip CH1 is an example of a first chip. The array chip CH2 is an example of a second chip.

The circuit chip CH1 functions as a control circuit (logic circuit) configured to control operation of the array chip CH2.

The circuit chip CH1 includes a semiconductor substrate 111, an interlayer insulating film 112, transistors (semiconductor elements) 113, metal pads BP1, and a metal pad WP.

The semiconductor substrate 111 is provided on a lower surface side of the circuit chip CH1. The semiconductor substrate 111 is, for example, a silicon (Si) substrate.

The interlayer insulating film 112 is provided on the semiconductor substrate 111. The interlayer insulating film 112 is, for example, a silicon oxide film or a multilayer film including a silicon oxide film and any other insulating film.

The plurality of transistors 113 are provided above the semiconductor substrate 111. The transistors 113 constitute a CMOS circuit as a control circuit of a memory cell array 123 of the array chip CH2. The control circuit is electrically connected to the metal pads BP1.

The metal pads BP1 are provided at a joining surface (bonding surface) S to the array chip CH2. The metal pads BP1 are joined to metal pads BP2 of the array chip CH2. The plurality of metal pads BP1 are, for example, Cu layers.

The metal pad WP is provided inside the circuit chip CH1. The metal pad WP is exposed from the circuit chip CH1 in a second region, which is different from a first region R1 in which the array chip CH2 is provided on an upper surface of the circuit chip CH1. The metal pad WP functions as an external connection pad (bonding pad) of the semiconductor chips 30 to 33. Specifically, the metal pad WP is connected to the bonding wire 90. Accordingly, the bonding wire 90 electrically connects the metal pad WP and the wiring substrate 10. The metal pad WP includes conductive metal such as aluminum (Al). The metal pad WP is an example of a first pad.

The array chip CH2 is joined (bonded) to the circuit chip CH1 on the circuit chip CH1 and electrically connected to the circuit chip CH1. The area of the array chip CH2 is smaller than the area of the circuit chip CH1. The areas of the circuit chip CH1 and the array chip CH2 are areas when viewed in the Z direction.

The array chip CH2 includes a semiconductor substrate 121, an interlayer insulating film 122, the memory cell array (semiconductor element) 123, a contact plug C1, and the metal pads BP2.

The semiconductor substrate 121 is provided on an upper surface side of the array chip CH2. The semiconductor substrate 121 is, for example, a silicon (Si) substrate.

The interlayer insulating film 122 is provided below the semiconductor substrate 121. The interlayer insulating film 122 is, for example, a silicon oxide film or a multilayer film including a silicon oxide film and any other insulating film.

The memory cell array 123 is provided below the semiconductor substrate 121. The memory cell array 123 is, for example, a non-volatile memory. The memory cell array 123 includes a staircase structure part. The memory cell array 123 is electrically connected to the metal pads BP2.

The contact plug C1 electrically connects a conductive layer (word line WL) of the memory cell array 123 and the metal pads BP2.

The metal pads BP2 are provided at the joining surface S to the circuit chip CH1. The metal pads BP2 are joined to the metal pads BP1 of the circuit chip CH1. The plurality of metal pads BP2 are, for example, Cu layers.

The spacer 101 is provided in a second region R2 different from a first region R1 in which the array chip CH2 is provided on the upper surface of the circuit chip CH1. An upper surface of the spacer 101 is substantially parallel to the upper surface of the array chip CH2. Specifically, a stepped part formed due to the area difference between the circuit chip CH1 and the array chip CH2 can be substantially flattened by the spacer 101. The spacer 101 of the semiconductor chip 30 supports the semiconductor chip 31 as illustrated in FIG. 4. Accordingly, the risk of chip tilt or the like at assembly can be reduced. Thus, the area of the upper surface of the array chip CH2 can be increased and stacking (die bonding) of the semiconductor chips 30 to 33 can be more appropriately performed.

The spacer 101 is provided apart from the bonding wire 90. The spacer 101 includes a recessed part 106. The recessed part 106 penetrates from an upper surface of the spacer 101 to a lower surface thereof. Accordingly, the upper surface of the circuit chip CH1 is exposed at a bottom surface of the recessed part 106. The bonding wire 90 extends through the recessed part 106 and is connected to the metal pad WP.

The spacer 101 includes resin. The resin is light-sensitive at manufacturing of the spacer 101. The resin includes, for example, epoxy resin. Alternatively, the resin may include at least one kind of poly benzo oxazole resin, phenol resin, and the like. In a case where the spacer 101 includes resin, the spacer 101 includes a filler F. Since the filler F exists on an inner surface of the recessed part 106, the recessed part 106 needs to have a large opening area (opening diameter) for connecting the bonding wire 90 to the metal pad WP.

The configuration of the memory cell array 123 and the transistors 113 will be described below.

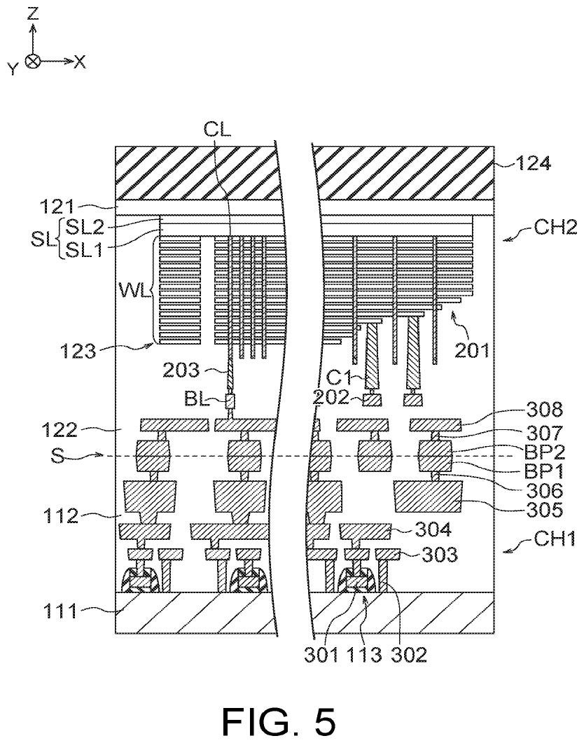

FIG. 5 is a cross sectional view illustrating an example of the configuration of the memory cell array 123 and the transistors 113 according to the first embodiment.

The array chip CH2 includes a plurality of word lines WL and a source line SL as electrode layers in the memory cell array 123. FIG. 5 illustrates a staircase structure part 201 of the memory cell array 123. Each word line WL is electrically connected to a word wiring layer 202 through the contact plug C1. A column-shaped part CL penetrating through the plurality of word lines WL is electrically connected to a bit line BL through a via plug 203 and electrically connected to the source line SL. The source line SL includes a first layer SL1 that is a semiconductor layer, and a second layer SL2 that is a metal layer.

The circuit chip CH1 includes the plurality of transistors 113. Each transistor 113 includes a gate electrode 301 provided on the semiconductor substrate 111 with a gate insulating film interposed therebetween, and a source diffusion layer and a drain diffusion layer provided in the semiconductor substrate 111, which are not illustrated. The circuit chip CH1 includes a plurality of contact plugs 302 each provided on the gate electrode 301, the source diffusion layer, or the drain diffusion layer of a transistor 113, a wiring layer 303 provided on the contact plugs 302 and including a plurality of pieces of wiring, and a wiring layer 304 provided on the wiring layer 303 and including a plurality of pieces of wiring.

The circuit chip CH1 also includes a wiring layer 305 provided on the wiring layer 304 and including a plurality of pieces of wiring, a plurality of via plugs 306 provided on the wiring layer 305, and the plurality of metal pads BP1 provided on the via plugs 306. The metal pads BP1 are, for example, Cu (copper) layers or Al (aluminum) layers.

The array chip CH2 includes the plurality of metal pads BP2 provided on the metal pads BP1, and a plurality of via plugs 307 provided on the metal pads BP2. The array chip CH2 also includes a wiring layer 308 provided on the via plugs 307 and including a plurality of pieces of wiring. The metal pads BP2 are, for example, Cu layers or Al layers.

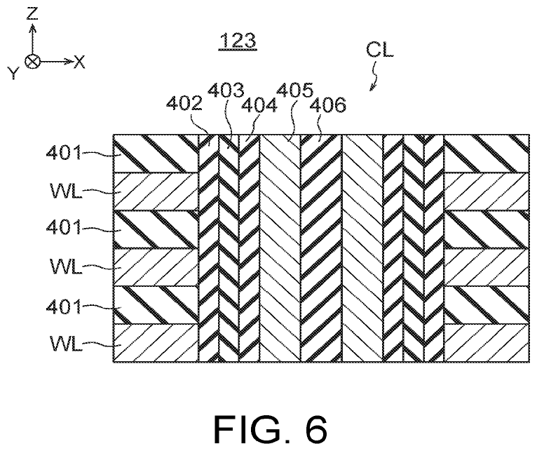

FIG. 6 is a cross sectional view illustrating an example of the configuration of the column-shaped part CL according to the first embodiment.

As illustrated in FIG. 6, the memory cell array 123 includes the plurality of word lines WL and a plurality of insulating layers 401 alternately stacked on the interlayer insulating film 122 (FIG. 5). Each word line WL is, for example, a W (tungsten) layer. Each insulating layer 401 is, for example, a silicon oxide film.

The column-shaped part CL sequentially includes a block insulating film 402, an electric charge accumulation layer 403, a tunnel insulating film 404, a channel semiconductor layer 405, and a core insulating film 406. The electric charge accumulation layer 403 is, for example, a silicon nitride film and formed on side surfaces of the word lines WL and the insulating layers 401 with the block insulating film 402 interposed therebetween. The electric charge accumulation layer 403 may be a semiconductor layer such as a polysilicon layer. The channel semiconductor layer 405 is, for example, a polysilicon layer and formed on a side surface of the electric charge accumulation layer 403 with the tunnel insulating film 404 interposed therebetween. The block insulating film 402, the tunnel insulating film 404, and the core insulating film 406 are each, for example, a silicon oxide film or a metal insulating film.

A method of manufacturing the semiconductor device 1 will be described below.

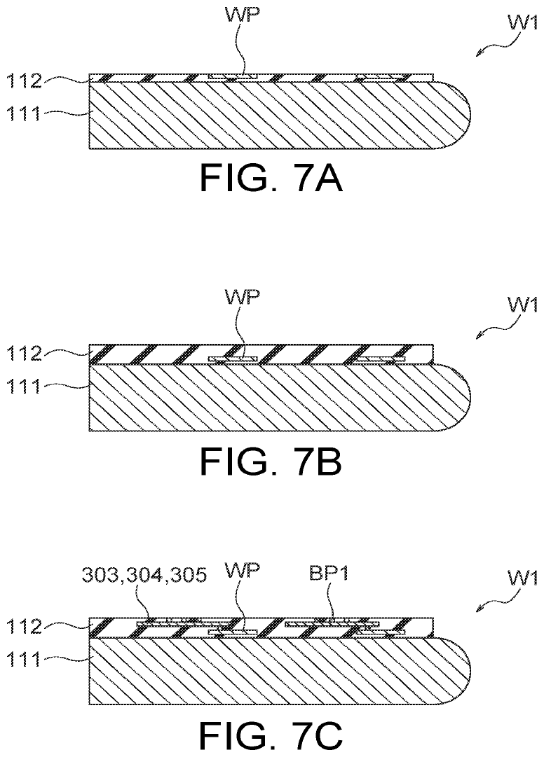

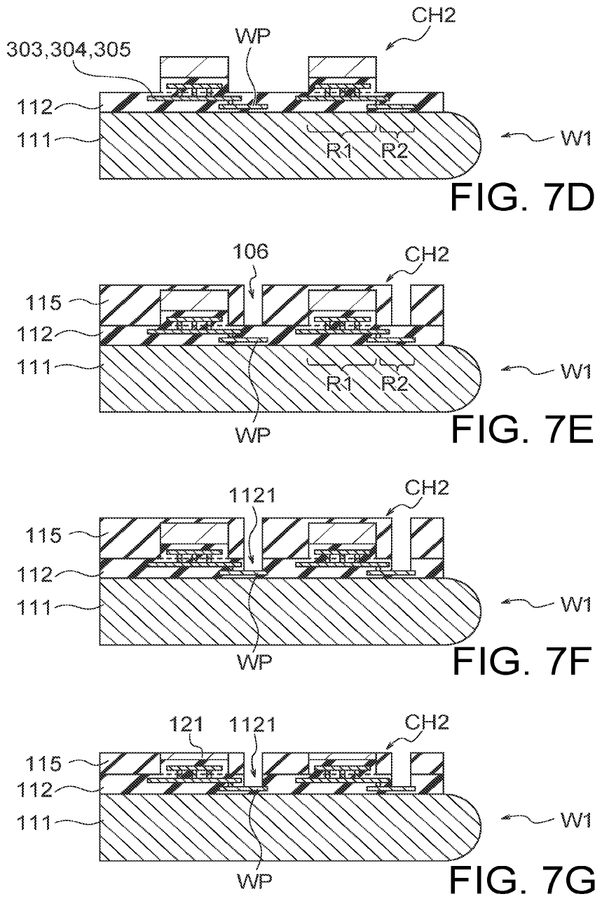

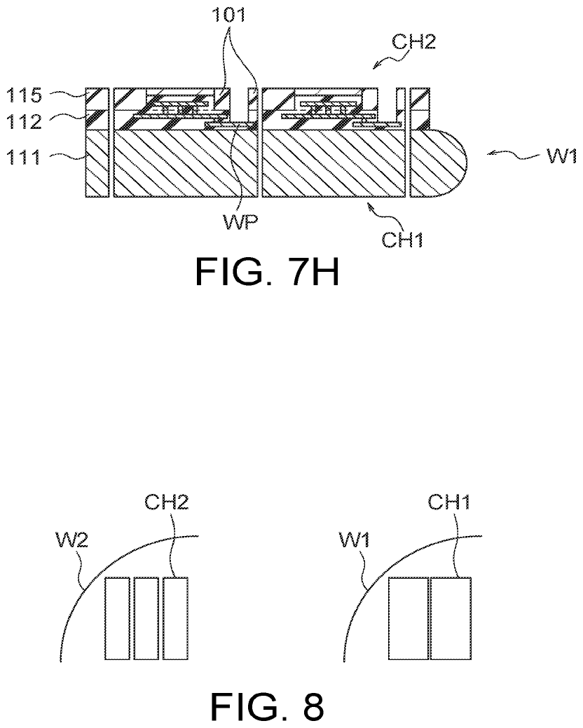

FIGS. 7A to 7H are cross sectional views illustrating an example of the method of manufacturing the semiconductor device 1 according to the first embodiment.

First, as illustrated in FIG. 7A, the metal pad WP is formed on a circuit wafer W1. The metal pad WP is, for example, an Al layer. The CMOS circuit constituted by the transistors 113 is already formed in a layer below the metal pad WP.

Subsequently, as illustrated in FIG. 7B, the interlayer insulating film 112 is formed on the metal pad WP and ground. Accordingly, a step due to the metal pad WP can be flattened. The formation of the interlayer insulating film 112 is performed by, for example, chemical vapor deposition (CVD). The grinding of the interlayer insulating film 112 is performed by, for example, chemical mechanical polishing (CMP).

Subsequently, as illustrated in FIG. 7C, the wiring layers 303, 304, and 305, the metal pads BP1, and the like are formed. The wiring layers 303, 304, and 305 and the metal pads BP1 are electrically connected to the metal pad WP. The wiring layers 303, 304, and 305 and the metal pads BP1 are, for example, Cu layers.

Subsequently, as illustrated in FIG. 7D, a plurality of array chips CH2 are joined to the circuit wafer W1. The metal pads BP1 and the metal pads BP2 illustrated in FIG. 3 are joined to each other. Accordingly, each array chip CH2 is joined to the circuit wafer W1 such that the circuit wafer W1 (circuit chip CH1) is electrically connected to the array chip CH2.

FIG. 8 is a diagram illustrating an example of the sizes of the circuit chip CH1 and the array chip CH2 according to the first embodiment. The size of each chip relative to a wafer is not limited to that in the example illustrated in FIG. 8.

As illustrated in FIG. 8, the area of the array chip CH2 is smaller than the area of the circuit chip CH1. Accordingly, as illustrated in FIG. 7D, the first region R1 in which the array chip CH2 is provided and the second region R2 in which no array chip CH2 is provided exist on the upper surface of the circuit chip CH1 (circuit wafer W1).

Subsequently, as illustrated in FIG. 7E, a member 115 is formed, and the recessed part 106 is formed in the member 115. The member 115 is formed on the circuit wafer W1 and the array chip CH2. The recessed part 106 is formed by partially removing the member 115 at a position where the metal pad WP is to be exposed. The recessed part 106 is formed in a region in which the metal pad WP is provided. The interlayer insulating film 112 is exposed at the bottom surface of the recessed part 106.

The member 115 includes a light-sensitive material such as light-sensitive resin. In this case, the recessed part 106 is formed by performing exposure and image development of the member 115. The light-sensitive material may be any of a positive light-sensitive material and a negative light-sensitive material. The light-sensitive material may include at least one kind of light-sensitive epoxy resin, light-sensitive poly benzo oxazole resin, light-sensitive phenol resin, and the like.

Subsequently, as illustrated in FIG. 7F, a recessed part 1121 is formed in the interlayer insulating film 112. The recessed part 1121 is formed by, for example, reactive ion etching (RIE). The recessed part 1121 communicates with the recessed part 106. The metal pad WP is exposed at a bottom surface of the recessed part 1121. Accordingly, the metal pad WP is exposed in the second region R2.

Subsequently, as illustrated in FIG. 7G, the member 115 is ground.

Subsequently, as illustrated in FIG. 7H, dicing and back grinding are performed. Accordingly, the circuit wafer W1 is singulated into a plurality of circuit chips CH1 (semiconductor chips 30 to 33). The spacer 101 illustrated in FIG. 3 is formed through the dicing of the member 115.

Thereafter, the semiconductor chips 30 to 33 formed through the process illustrated in FIG. 7H are mounted on the wiring substrate 10 and a package assembling process is performed. Accordingly, the semiconductor device 1 illustrated in FIGS. 1 to 3 is completed.

The order illustrated in FIGS. 7A to 7H is an example. For example, the process illustrated in FIG. 7F may be performed after the process illustrated in FIG. 7G.

In FIGS. 7A to 7C, the metal pad WP may be formed in the same layer as the wiring layers 303, 304, and 305 and the metal pads BP1. In this case, the metal pad WP is a Cu layer. The metal pad WP may be formed of conductive metal other than Al and Cu.

In FIG. 7D, it is difficult to join thin array chips CH2 to the circuit wafer W1 (chip bonding) in some cases. In such a case, chip bonding may be performed with array chips CH2 being thick to some extent, and thereafter, the array chips CH2 may be thinned.

In the process illustrated in FIG. 7E, the member 115 may be flattened before exposure and image development of the member 115. Accordingly, pattern formation through exposure can be more appropriately performed.

As described above, according to the first embodiment, the area of each array chip CH2 is smaller than the area of each circuit chip CH1. The circuit chip CH1 includes the metal pad WP exposed from the circuit chip CH1 in the second region R2, which is different from the first region R1 in which the array chip CH2 is provided on the upper surface of the circuit chip CH1. Accordingly, as illustrated in FIG. 8, it is possible to reduce waste on the array wafer W2 along with miniaturization of the memory cell array 123. Thus, it is possible to form a larger number of array chips CH2 on the array wafer W2.

### Comparative Example

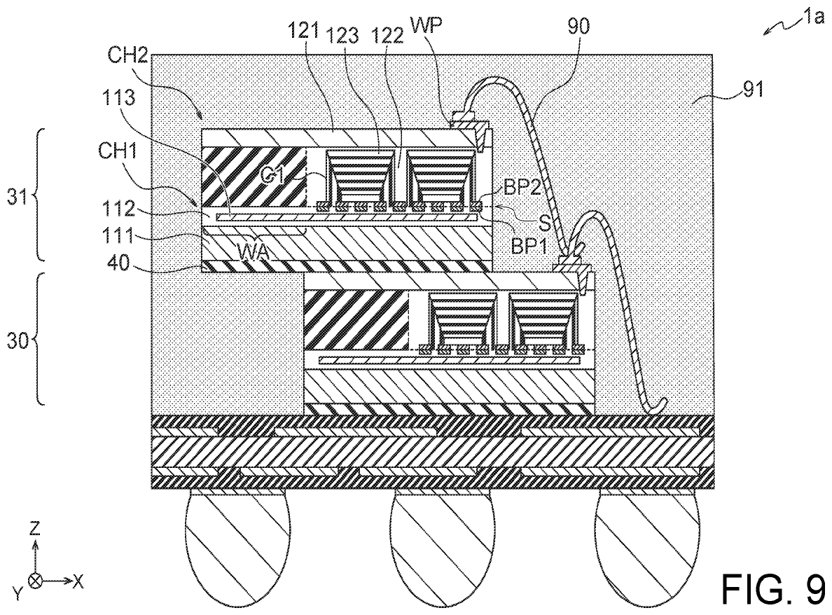

FIG. 9 is a cross sectional view illustrating an example of the configuration of a semiconductor device 1a according to a comparative example. The comparative example is different from the first embodiment in that the area of the array chip CH2 is substantially equal to the area of the circuit chip CH1.

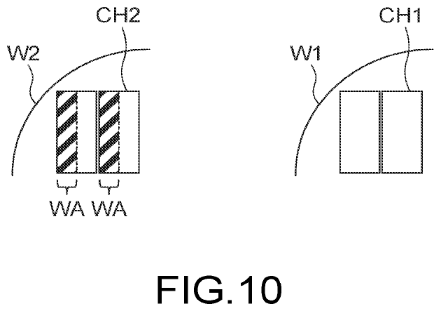

FIG. 10 is a diagram illustrating an example of the sizes of the circuit chip CH1 and the array chip CH2 according to the comparative example.

As illustrated in FIG. 10, the area of the array chip CH2 is substantially equal to the area of the circuit chip CH1. In the comparative example, the semiconductor chips 30 to 33 are formed by bonding the circuit wafer W1 and the array wafer W2 to each other and singulating the bonded wafers. However, a mismatch between the element area of the array chip CH2 and the element area of the circuit chip CH1 increases along with miniaturization of the memory cell array 123. In this case, as illustrated in FIGS. 9 and 10, the area of a region WA increases as the element area of the memory cell array 123 decreases. The region WA is an unnecessary region in which the memory cell array 123 is not provided on the array chip CH2.

However, in the first embodiment, a plurality of array chips CH2 are joined to the circuit wafer W1 as illustrated in FIG. 7D. As illustrated in FIG. 8, the memory cell array 123 is formed without providing the unnecessary region WA on the array wafer W2. Accordingly, the unnecessary region WA can be eliminated, and a larger number of array chips CH2 can be formed on the array wafer W2.

Another comparative example in which the metal pad WP is provided on the upper surface of the array chip CH2 will be described below. In the semiconductor chips 30 to 33 illustrated in FIG. 3, for example, the metal pad WP is provided on the upper surface of the array chip CH2 as illustrated in FIG. 9. However, in this case, a film needs to be formed on a surface (refer to FIG. 7G, for example) where the semiconductor substrate 121 and the member 115 (spacer 101) exist in mixture. The film is formed by, for example, a spin coat method. The film includes, for example, a protective film (passivation film) or a resist. The protective film is, for example, an insulating film 124 illustrated in FIG. 5 and includes, for example, polyimide. Since the semiconductor substrate 121 and the member 115 exist in mixture on the surface, it is difficult to appropriately (for example, uniformly) form the film. As a result, it is difficult to form the metal pad WP.

However, in the first embodiment, as illustrated in FIG. 7E, the member 115 in which the array chip CH2 is embedded includes the light-sensitive material. Thus, fabrication can be performed toward the metal pad WP on the lower side of the member 115. Accordingly, it is possible to more easily form the metal pad WP. Moreover, in the first embodiment, fabrication such as lithography is not performed on the surface on which the semiconductor substrate 121 and the member 115 exist in mixture. Thus, it is possible to simplify fabrication for forming the metal pad WP since the metal pad WP is not provided on the upper surface of the array chip CH2.

### Second Embodiment

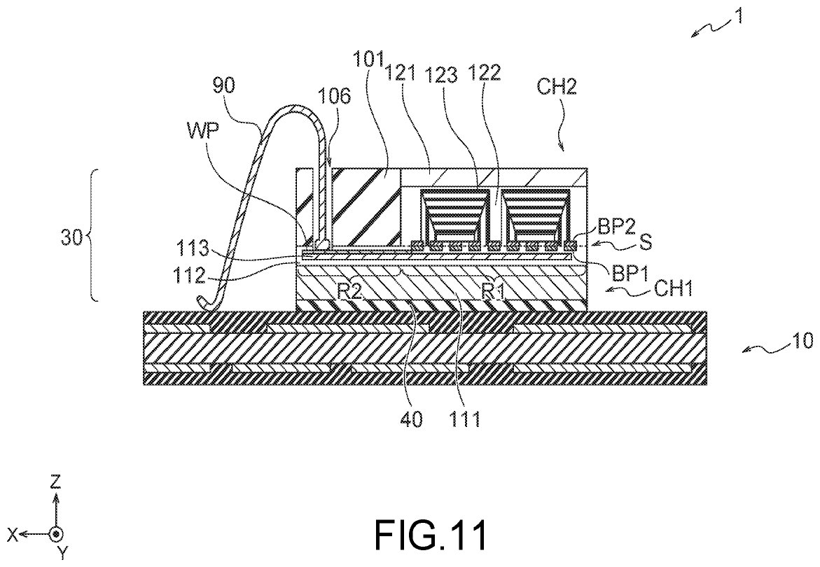

FIG. 11 is a cross sectional view illustrating an example of the configuration of the semiconductor device 1 according to a second embodiment. The second embodiment is different from the first embodiment in the material of the spacer 101.

The resin included in the spacer 101 is polyimide. The polyimide resin of the present embodiment includes no filler F. The polyimide resin of the present embodiment is light-sensitive at manufacturing. Since no filler F is included, the opening area of the recessed part 106 can be smaller than in the first embodiment in manufacturing through exposure and image development as in the first embodiment.

The material of the spacer 101 may be changed as in the second embodiment. With the semiconductor device 1 according to the second embodiment, it is possible to obtain the same effects as in the first embodiment. By using light-sensitive resin including no filler F, it is possible to obtain the same effects as in the second embodiment even in a case where the resin is other than polyimide.

### Third Embodiment

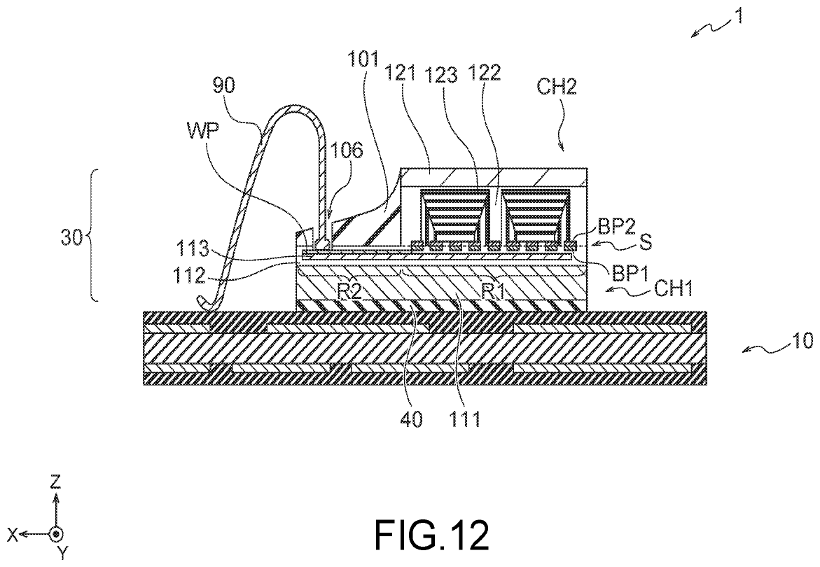

FIG. 12 is a cross sectional view illustrating an example of the configuration of the semiconductor device 1 according to a third embodiment. The third embodiment is different from the first embodiment in the shape of the spacer 101.

The upper surface of the spacer 101 is not flat. In a case where the array chip CH2 has a relatively large thickness in the Z direction, the upper surface of the spacer 101 has a slope as illustrated in FIG. 12 in some cases.

The upper surface of the spacer 101 is positioned lower than the upper surface of the array chip CH2. More specifically, the recessed part 106 has an upper end positioned lower than the upper surface of the array chip CH2. Accordingly, the bonding wire 90 can be easily connected to the metal pad WP. Moreover, the opening area of the recessed part 106 can be reduced.

The shape of the spacer 101 may be changed as in the third embodiment. With the semiconductor device 1 according to the third embodiment, it is possible to obtain the same effects as in the first embodiment.

### Fourth Embodiment

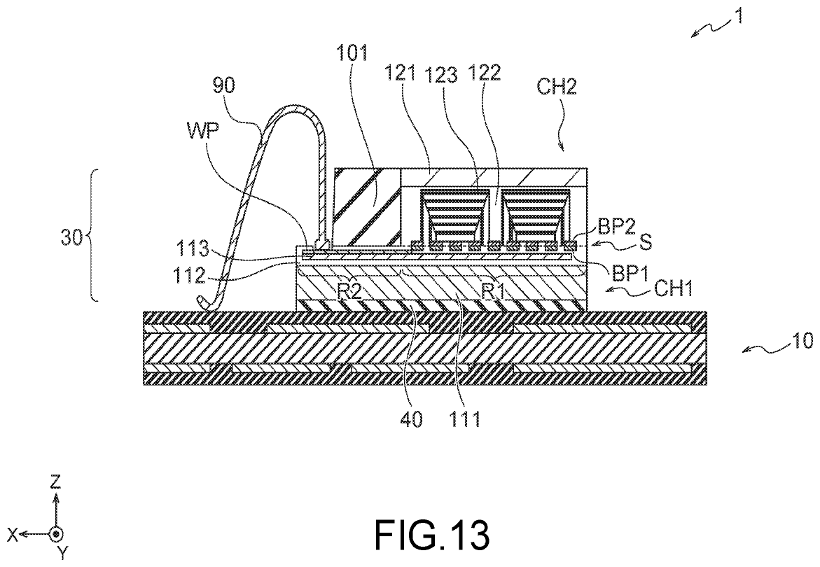

FIG. 13 is a cross sectional view illustrating an example of the configuration of the semiconductor device 1 according to a fourth embodiment. The fourth embodiment is different from the first embodiment in the shape of the spacer 101.

The spacer 101 is provided with a void space in the second region R2 in an area on the opposite side of the exposed metal pad WP from the array chip CH2. In other words, the spacer 101 is not provided in a region outside the semiconductor chip 30 beyond the metal pad WP connected to the bonding wire 90. Accordingly, the bonding wire 90 can be easily connected to the metal pad WP.

The shape of the spacer 101 may be changed as in the fourth embodiment. With the semiconductor device 1 according to the fourth embodiment, it is possible to obtain the same effects as in the first embodiment.

### Fifth Embodiment

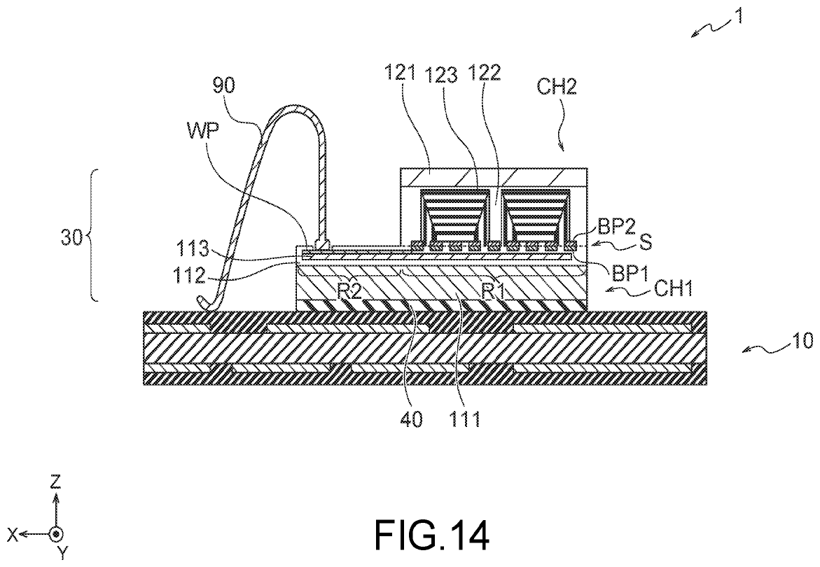

FIG. 14 is a cross sectional view illustrating an example of the configuration of the semiconductor device 1 according to a fifth embodiment. The fifth embodiment is different from the first embodiment in that no spacer 101 is provided and no member 115 to be the spacer 101 after singulation is formed.

Since no spacer 101 is provided, the bonding wire 90 can be easily connected to the metal pad WP.

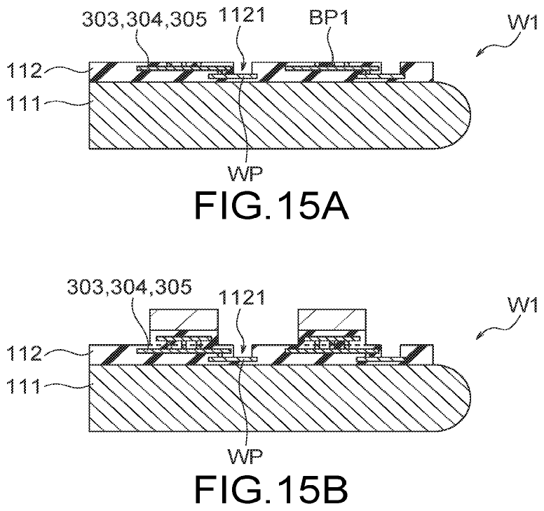

FIGS. 15A and 15B are cross sectional views illustrating an example of a method of manufacturing the semiconductor device 1 according to the fifth embodiment. The process illustrated in FIG. 15A is performed after the same processes as in FIGS. 7A to 7C.

After the wiring layers 303, 304, and 305, the metal pads BP1, and the like are formed (refer to FIG. 7C), the recessed part 1121 is formed in the interlayer insulating film 112 as illustrated in FIG. 15A. The recessed part 1121 is formed by, for example, RIE. The recessed part 1121 extends from an upper surface of the interlayer insulating film 112 (upper surface of the circuit wafer W1) to the metal pad WP. The metal pad WP is exposed at the bottom surface of the recessed part 1121.

Subsequently, as illustrated in FIG. 15B, a plurality of array chips CH2 are joined to the circuit wafer W1. It is possible to lower difficulty of a lithography process by forming the recessed part 1121 before joining each array chip CH2.

Thereafter, the circuit wafer W1 is singulated into a plurality of circuit chips CH1 (semiconductor chips 30 to 33) by dicing and the semiconductor chip 30 is mounted on the wiring substrate 10 (refer to FIG. 14).

No spacer 101 may be provided as in the fifth embodiment. With the semiconductor device 1 according to the fifth embodiment, it is possible to obtain the same effects as in the first embodiment.

### Sixth Embodiment

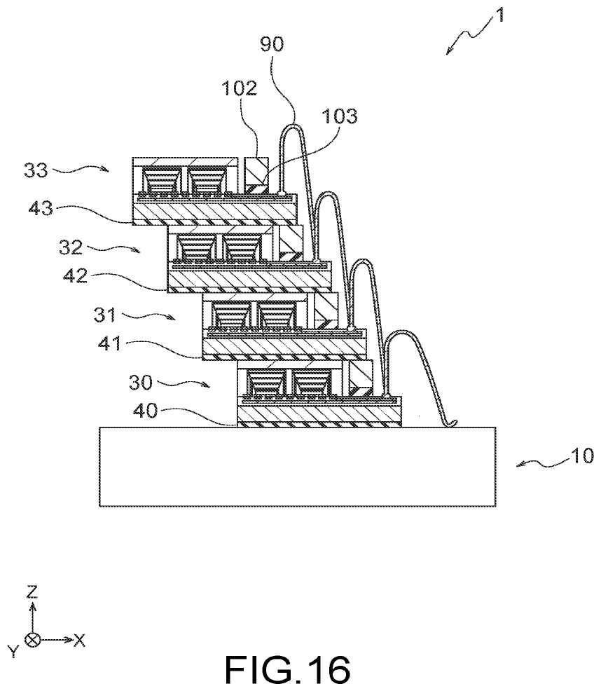

FIG. 16 is a cross sectional view illustrating an example of the configuration of the semiconductor device 1 according to a sixth embodiment. The sixth embodiment is different from the first embodiment in the configuration of the spacer 101.

The spacer 101 includes a spacer chip 102 and a bonding layer 103.

An upper surface of the spacer chip (dummy chip) 102 is substantially parallel to the upper surface of the array chip CH2.

The bonding layer 103 is provided between the circuit chip CH1 and the spacer chip 102. The bonding layer 103 is, for example, a die attach film (DAF).

The spacer chip 102 includes, for example, silicon (Si). However, the spacer chip is not limited thereto, and for example, may be resin. The spacer chip 102 preferably includes, for example, a material harder than the spacer 101 in the first embodiment. Accordingly, the semiconductor chips 30 to 33 stacked on the spacer 101 can be more appropriately supported. Moreover, the spacer chip 102 preferably includes a material having a thermal expansion coefficient lower than that of the spacer 101 in the first embodiment. Accordingly, the height of the spacer 101 can be easily adjusted. As a result, the semiconductor chips 30 to 33 stacked on the spacer 101 can be more appropriately supported.

The configuration of the spacer 101 may be changed as in the sixth embodiment. With the semiconductor device 1 according to the sixth embodiment, it is possible to obtain the same effects as in the first embodiment.

### Seventh Embodiment

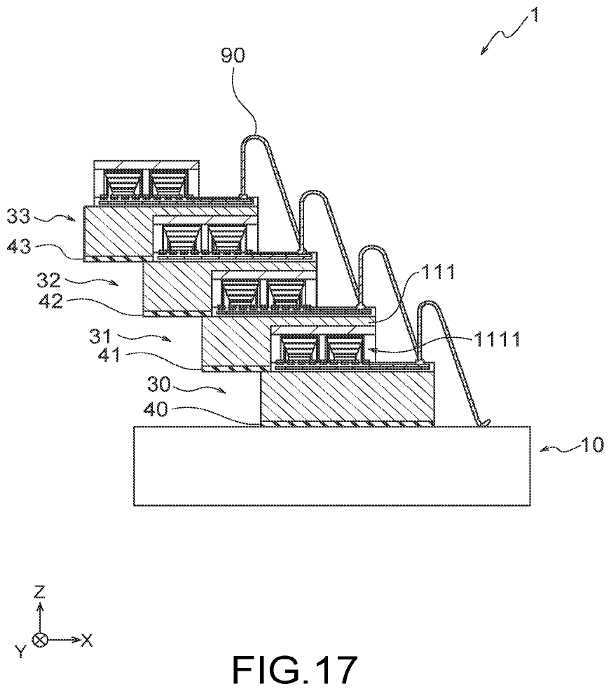

FIG. 17 is a cross sectional view illustrating an example of the configuration of the semiconductor device 1 according to a seventh embodiment. The seventh embodiment is different from the first embodiment in the configuration of the semiconductor substrate 111.

As illustrated in FIG. 17, the semiconductor chip 31 is stacked on the semiconductor chip 30. The semiconductor chip 32 is stacked on the semiconductor chip 31. The semiconductor chip 33 is stacked on the semiconductor chip 32. The two semiconductor chips 30 and 31 will be described below.

The semiconductor substrate 111 included in the circuit chip CH1 of the semiconductor chip 31 has a recessed part 1111 in which the array chip CH2 of the semiconductor chip 30 is housed. The depth of the recessed part 1111 in the Z direction corresponds to, for example, the height of the array chip CH2. Accordingly, the semiconductor chip 31 can be more appropriately supported even in a case where no spacer 101 is provided.

Similarly to the case of the semiconductor chip 31, the semiconductor substrate 111 included in the circuit chip CH1 of each of the semiconductor chips 32 and 33 has the recessed part 1111. As illustrated in FIG. 17, the semiconductor substrate 111 included in the circuit chip CH1 of the semiconductor chip 30 at the lowermost layer may have no recessed part 1111.

The configuration of the semiconductor substrate 111 may be changed as in the seventh embodiment. With the semiconductor device 1 according to the seventh embodiment, it is possible to obtain the same effects as in the first embodiment.

### Eighth Embodiment

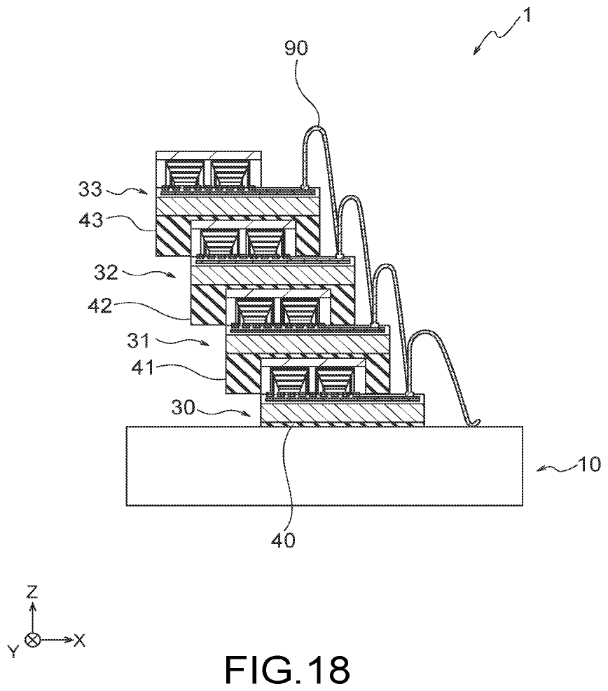

FIG. 18 is a cross sectional view illustrating an example of the configuration of the semiconductor device 1 according to an eighth embodiment. The eighth embodiment is different from the first embodiment in the configurations of the bonding layers 41 to 43.

The bonding layer 41 is provided between the semiconductor chips 30 and 31. The bonding layer 42 is provided between the semiconductor chips 31 and 32. The bonding layer 43 is provided between the semiconductor chips 32 and 33. The two semiconductor chips 30 and 31 will be described below.

The bonding layer 41 provided on a lower surface of the semiconductor chip 31 is provided covering the array chip CH2 of the semiconductor chip 30. Thus, the bonding layer 41 is provided thick enough to cover the array chip CH2. Accordingly, the semiconductor chip 31 can be more appropriately supported even in a case where no spacer 101 is provided.

Similarly to the bonding layer 41, the bonding layers 42 and 43 provided on lower surfaces of the semiconductor chips 32 and 33, respectively, are provided thick enough to cover the array chip CH2. As illustrated in FIG. 18, the bonding layer 40 provided on a lower surface of the semiconductor chip 30 at the lowermost layer does not necessarily need to be provided thick.

The configurations of the bonding layers 41 to 43 may be changed as in the eighth embodiment. With the semiconductor device 1 according to the eighth embodiment, it is possible to obtain the same effects as in the first embodiment.

### Ninth Embodiment

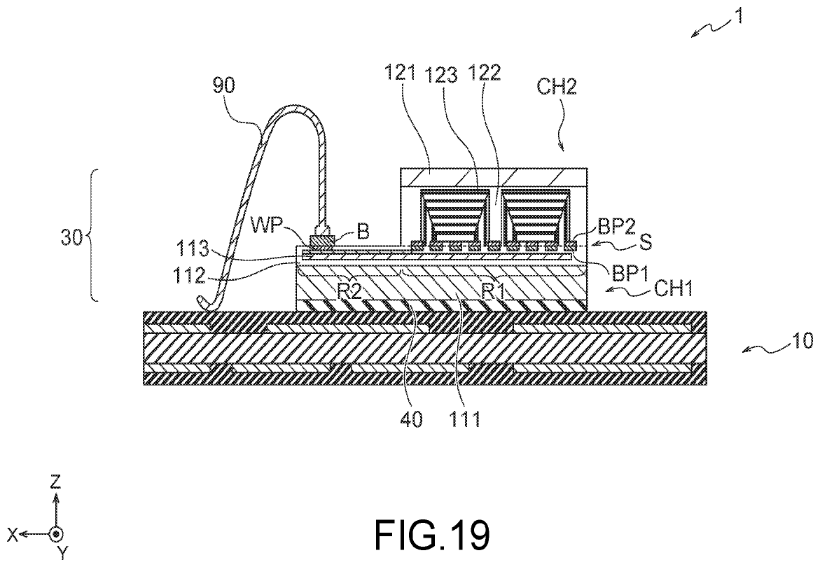

FIG. 19 is a cross sectional view illustrating an example of the configuration of the semiconductor device 1 according to a ninth embodiment. The ninth embodiment is different from the fifth embodiment in that a metal bump B is provided below the bonding wire 90.

The metal pad WP has an upper surface substantially parallel to the upper surface of the circuit chip CH1. The metal pad WP is exposed from the circuit chip CH1 at the upper surface of the circuit chip CH1.

The semiconductor device 1 further includes the metal bump B. The metal bump B is provided on the metal pad WP and connected to the bonding wire 90. The metal bump B is provided between the bonding wire 90 and the metal pad WP.

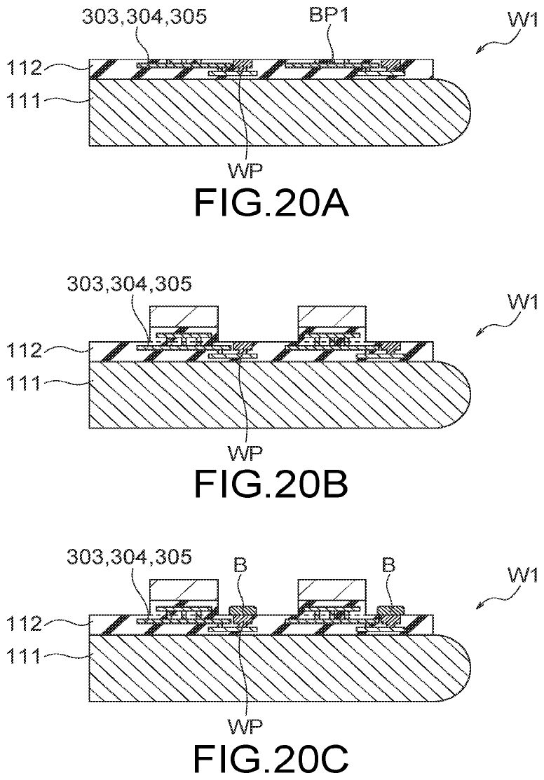

FIGS. 20A to 20C are cross sectional views illustrating an example of a method of manufacturing the semiconductor device 1 according to the ninth embodiment.

First, as illustrated in FIG. 20A, the wiring layers 303, 304, and 305, the metal pads BP1 and WP, and the like are formed. The wiring layers 303, 304, and 305 and the metal pads BP1 are electrically connected to the metal pad WP. The wiring layers 303, 304, and 305 and the metal pads BP1 and WP are, for example, Cu layers. The metal pad WP is exposed from the circuit wafer W1 and substantially flat.

Subsequently, as illustrated in FIG. 20B, a plurality of array chips CH2 are joined to the circuit wafer W1.

Subsequently, as illustrated in FIG. 20C, the metal bump B is formed on the metal pad WP. Thus, a bonding pad can be formed without using lithography after the array chips CH2 are joined. The metal bump B includes one metal layer or a plurality of stacked metal layers formed by, for example, non-electrolytic plating. Each metal layer includes, for example, Ni, Pd, or Au.

Thereafter, the circuit wafer W1 is singulated into a plurality of circuit chips CH1 (semiconductor chips 30 to 33) by dicing and the semiconductor chip 30 is mounted on the wiring substrate 10 (refer to FIG. 19).

The metal bump B may be provided below the bonding wire 90 as in the ninth embodiment. With the semiconductor device 1 according to the ninth embodiment, it is possible to obtain the same effects as in the fifth embodiment. The spacer 101 may be provided as in, for example, the first embodiment. In this case, for example, the same process as the process illustrated in FIG. 7E is performed after the process illustrated in FIG. 20B or after the process illustrated in FIG. 20C. Moreover, the spacer chip 102 may be provided as the spacer 101 as in the sixth embodiment.

### Tenth Embodiment

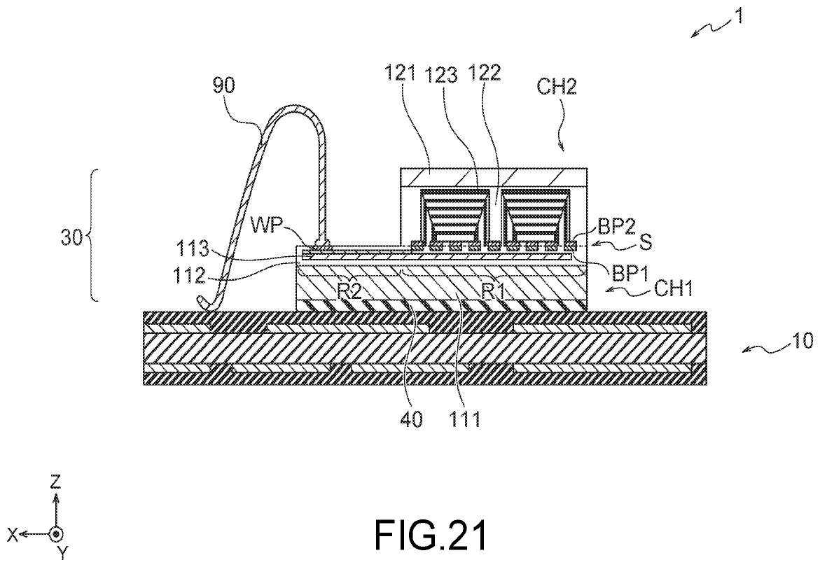

FIG. 21 is a cross sectional view illustrating an example of the configuration of the semiconductor device 1 according to a tenth embodiment. The tenth embodiment is different from the fifth embodiment in that the metal pad WP below the bonding wire 90 is substantially flat relative to the upper surface of the circuit chip CH1. In other words, the tenth embodiment is different from the ninth embodiment in that no metal bump B is provided.

The upper surface of the metal pad WP is substantially parallel to the upper surface of the circuit chip CH1. The metal pad WP is connected to the bonding wire 90.

The process illustrated in FIG. 20C in the ninth embodiment is not performed in the tenth embodiment. Thus, the number of processes can be reduced by using the metal pad WP as a bonding pad.

The metal pad WP below the bonding wire 90 may be substantially flat relative to the upper surface of the circuit chip CH1 as in the tenth embodiment. With the semiconductor device 1 according to the tenth embodiment, it is possible to obtain the same effects as in the fifth embodiment. The spacer 101 may be provided as in, for example, the first embodiment. In this case, for example, the same process as the process illustrated in FIG. 7E is performed after the process illustrated in FIG. 20B. Moreover, the spacer chip 102 may be provided as the spacer 101 as in the sixth embodiment.

### Eleventh Embodiment

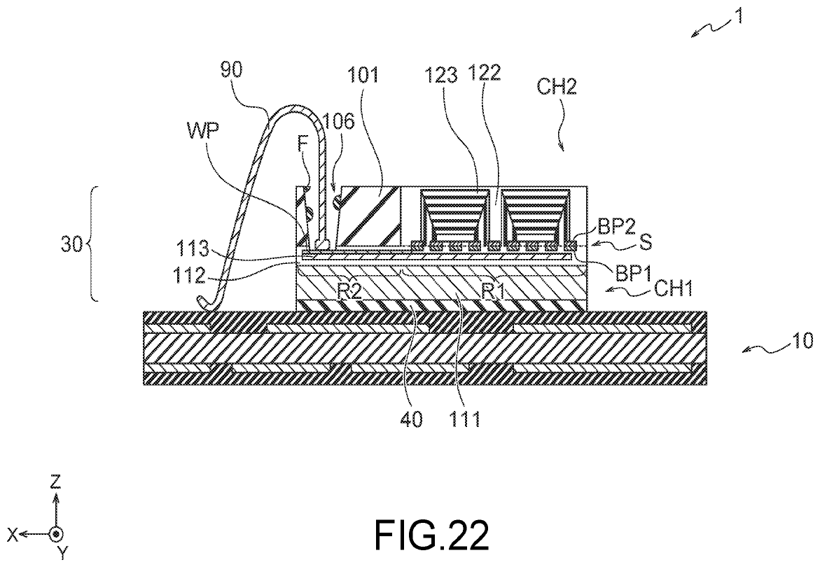

FIG. 22 is a cross sectional view illustrating an example of the configuration of the semiconductor device 1 according to an eleventh embodiment. The eleventh embodiment is different from the first embodiment in that no semiconductor substrate 121 of the array chip CH2 is provided.

The array chip CH2 includes no semiconductor substrate 121 on the upper surface side. Accordingly, the height of the array chip CH2 is lowered. In addition, the height of the spacer 101 is lowered since no semiconductor substrate 121 is provided. Moreover, the height of the semiconductor package is lowered since the height of the array chip CH2 of each of the semiconductor chips 30 to 33 is lowered.

In the process illustrated in FIG. 7D, the array chip CH2 from which the semiconductor substrate 121 is removed (completely peeled off) in advance may be joined to the circuit wafer W1, or the semiconductor substrate 121 may be removed (fully peeled off) after the process illustrated in FIG. 7D. The removal of the semiconductor substrate 121 is performed by, for example, wet etching.

No semiconductor substrate 121 of the array chip CH2 may be provided as in the eleventh embodiment. With the semiconductor device 1 according to the eleventh embodiment, it is possible to obtain the same effects as in the first embodiment.

### Other Embodiments

(a) In the above-described embodiments, the array chip CH2 of each of the semiconductor chips 30 to 33 includes a stereoscopic memory cell array in which a plurality of memory cells are three-dimensionally disposed. Instead, the array chip CH2 may be, for example, a two-dimensional memory cell array or an image sensor. Alternatively, the array chip CH2 may be any other memory element such as a DRAM or an SRAM instead of a NAND type flash memory. The array chip CH2 may be, for example, a CMOS circuit element.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device including a semiconductor chip comprising:
a first chip; and
a second chip joined to the first chip on the first chip and electrically connected to the first chip, wherein
the area of the second chip is smaller than the area of the first chip, and
the first chip includes a first pad exposed from the first chip in a second region, the second region being different from a first region in which the second chip is provided on an upper surface of the first chip.

2. The semiconductor device according to claim 1, further comprising:
a wiring substrate on which the semiconductor chip is mounted; and
a wire electrically connecting the first pad and the wiring substrate.

3. The semiconductor device according to claim 2, further comprising a spacer provided in the second region, wherein the spacer is provided apart from the wire.

4. The semiconductor device according to claim 3, wherein the spacer includes resin.

5. The semiconductor device according to claim 4, wherein the resin includes at least one of polyimide, poly benzo oxazole, phenol, and epoxy.

6. The semiconductor device according to claim 3, wherein an upper surface of the spacer is substantially parallel to an upper surface of the second chip.

7. The semiconductor device according to claim 3, wherein the upper surface of the spacer is positioned lower than an upper surface of the second chip.

8. The semiconductor device according to claim 3, wherein the spacer is provided with a void space in the second region in an area on an opposite side of the exposed first pad from the second chip.

9. The semiconductor device according to claim 3, wherein the spacer includes a spacer chip having an upper surface substantially parallel to the upper surface of the second chip.

10. The semiconductor device according to claim 1, comprising:
a first semiconductor chip including the first chip and the second chip; and
a second semiconductor chip including a third chip and a fourth chip and stacked on the first semiconductor chip, the third chip having a similar configuration as the first chip, and the fourth chip having a similar configuration as the second chip, wherein
the first chip and the third chip each further include a semiconductor substrate provided on a lower surface side, and
the semiconductor substrate included in the third chip of the second semiconductor chip includes a recessed part in which the second chip of the first semiconductor chip is housed.

11. The semiconductor device according to claim 1, comprising:
a first semiconductor chip including the first chip and the second chip;
a second semiconductor chip including a third chip and a fourth chip and stacked on the first semiconductor chip, the third chip having a similar configuration as the first chip, and the fourth chip having a similar configuration as the second chip; and
a bonding layer provided between the first semiconductor chip and the second semiconductor chip,
wherein the bonding layer is provided covering the second chip of the first semiconductor chip.

12. The semiconductor device according to claim 1, wherein
the first pad is provided inside the first chip, and
the first chip further includes a recessed part extending from the upper surface of the first chip to the first pad.

13. The semiconductor device according to claim 1, wherein the first pad has an upper surface substantially parallel to the upper surface of the first chip.

14. The semiconductor device according to claim 13, further comprising a metal bump provided on the first pad.

15. The semiconductor device according to claim 1, wherein the second chip has no semiconductor substrate on an upper surface side.

16. A semiconductor device manufacturing method comprising:
forming a first pad on a wafer yet to be singulated into a first chip;
joining a second chip in a first region on an upper surface of the wafer; and
exposing the first pad in a second region different from in the first region on the upper surface of the wafer,
wherein the area of the second chip is smaller than the area of the first chip.

17. The semiconductor device manufacturing method according to claim 16, further comprising, after the joining of the second chip:
forming a member on the wafer and the second chip; and
partially removing the member at a position where the first pad is to be exposed.

18. The semiconductor device manufacturing method according to claim 17, wherein
the member includes a light-sensitive material, and
the partial removing of the member includes exposure and image development of the member.
